(19) United States
(12) Patent Application Publication
(10) Pub. No.: US 2014/0029152 A1
(43) Pub. Date: Jan. 30, 2014

(54) SOLID-STATE CIRCUIT BREAKERS

(71) Applicants: Michael MAZZOLA, Starkville, MS (US); Robin KELLEY, Starkville, MS (US)

(72) Inventors: Michael MAZZOLA, Starkville, MS (US); Robin KELLEY, Starkville, MS (US)

(73) Assignee: SEMISOUTH LABORATORIES, INC., Starkville, MS (US)

(21) Appl. No.: 13/435,377

(22) Filed: Mar. 30, 2012

(51) Int. Cl. H03K 17/687

(52) U.S. Cl. CPC H03K 17/6871
USPC 361/115

(57) ABSTRACT

A fast acting unidirectional or bidirectional electronic circuit breaker for isolating a load from a power-supply unit is described. The described control method for an electronic circuit breaker is capable of instantaneous trip during a short circuit event by improved means of current sensing. The improved control method eliminates the need for additional series components in the conduction path which can add to the circuit breaker's insertion losses. Also, any delay or bandwidth limitations commonly associated with magnetic or hall-effect current sensing methods are eliminated. Circuit breakers with automatic or manual reset options are also described.

### STATEMENT REGARDING FEDERALLY SPONSORED RESEARCH

This invention was made with government support under Contract No. W56 HZV-09-C-0159 awarded by the United States Army, Office of the Secretary of Defense (OSD). The government has certain rights in the invention.

The section headings used herein are for organizational purposes only and should not be construed as limiting the subject matter described herein in any way.

### BACKGROUND

1. Field

This application relates generally to over-current and/or over-voltage protection devices for use in electrical circuits and, in particular, to solid-state circuit breakers and circuits comprising the circuit breakers.

2. Background of the Technology

Industrial electrical applications, as well as many other areas, require the use of circuit breakers to meet certain safety measures. These circuit breakers are in place to provide disconnect points as well as fault protection for electrical systems. Short circuit, over current, and over voltage faults are three common faults detected and controlled by circuit breakers. The shortcomings of fuses and/or mechanical circuit breakers have been improved upon by electronic or solid state circuit breakers. For example, the nature of a fuse is such that during an over-current event the fuse “blows” meaning it becomes an indefinite open circuit. One risk of using fuses is that at start-up of a system a fuse may blow due to normal over currents present during start up only or may have already failed for an unknown reason and require replacement. Mechanical circuit breakers tend to be subject to vibration causing a false trip condition and for smaller, less capable units, may have to be physically reset when tripped. Those that can be reset remotely require expensive and heavy electromechanical actuators that are especially undesirable for mobile applications such as in aircraft or automobiles. Electromechanical relays are heavy, have slow response time, are prone to mechanical wear-out limiting the component reliability and lifetime, can create electrical discharge such as arcing that limits their insertion into dangerous or explosive environmental conditions, and are known to create spurious electrical noise.

Solid-state circuit breakers exist to overcome many of the disadvantages of mechanical circuit breakers.

There still exists a need, however, for solid-state circuit breakers having low insertion losses and sufficient bandwidth to detect and disconnect quickly when fault conditions occur.

### SUMMARY

A circuit breaker is provided which comprises:

a first saturable unipolar switch comprising a source a gate and a drain;

a first diode connected between the source and the drain of the first saturable unipolar switch, wherein the cathode of the first diode is connected to the drain of the first saturable unipolar switch; and

a controller adapted to detect current generated upon the onset of saturation in the first saturable unipolar switch, wherein the controller is adapted to supply a first voltage to the gate of the first saturable unipolar switch when saturation of the first saturable unipolar switch is not detected, wherein the controller is adapted to supply a second voltage to the gate of the first saturable unipolar switch when saturation of the first saturable unipolar switch is detected, and wherein the first saturable unipolar switch is in an on state when the first voltage is applied to the gate and in an off state when the second voltage is applied to the gate.

The circuit breaker can further comprise:

a second saturable unipolar switch comprising a source a gate and a drain, wherein the source of the second saturable unipolar switch is connected to the source of the first saturable unipolar switch; and

a second diode connected between the source and the drain of the second saturable unipolar switch, wherein the cathode of the second diode is connected to the drain of the second saturable unipolar switch; and

wherein the controller is adapted to detect current generated upon the onset of saturation in the second saturable unipolar switch, wherein the controller is adapted to supply the first voltage to the gate of the second saturable unipolar switch when saturation of the second saturable unipolar switch is not detected and wherein the controller is adapted to supply the second voltage to the gate of the second saturable unipolar switch when saturation of the second saturable unipolar switch is detected, and wherein the second saturable unipolar switch is in an on state when the first voltage is applied to the gate and in an off state when the second voltage is applied to the gate.

A circuit comprising a circuit breaker as set forth above is also provided.

An advantage of the invention is the simplicity of operation in detecting the over current condition and the certainty by which the fact of an over current condition is translated into an appropriate response. The use of saturable unipolar devices to both conduct normal current and to respond correctly to excessive current ensures error free detection of the over current condition at the same speed by which the over current condition can physically occur in the switch. Hence, unlike prior art, the method disclosed is not subject to the limitations of normal sensors of the over current condition. In addition, the method embodied in the controller circuit is inherently responsive to the fact that saturation of the unipolar device has occurred. By design, the response of the controller is directly caused by the effects of saturation of the unipolar switch in the path of the over current. Hence, unlike prior art, the method disclosed is not subject to the limitations of normal sensors of switch saturation. The combination of these two advantages is an innovation unknown in solid-state circuit breakers.

These and other features of the present teachings are set forth herein.

### BRIEF DESCRIPTION OF THE DRAWINGS

The skilled artisan will understand that the drawings, described below, are for illustration purposes only. The drawings are not intended to limit the scope of the present teachings in any way.

FIG. 1 is a schematic representation of a solid state circuit breaker for circuits carrying alternating current.

FIG. 2 is a schematic representation of a solid state circuit breaker for circuits carrying direct current.

FIG. 3 is a graph showing trip delay curves for a solid state circuit breaker with 1200-V vertical-channel JFETs.

FIG. 4A-4C are schematics of various embodiments of solid state circuit breaker control circuits in conjunction with saturable unipolar switches.

FIG. 5 shows the response of a discrete bi-directional solid state circuit breaker comprising two 1200-V, 7-A normally-off JFETs to hard fault conditions.

FIG. 6 shows the response of the control circuit driving a 1200-V, 100-A, normally-off JFET based solid state circuit breaker to hard fault conditions.

FIG. 7 shows measured waveforms for the 1200-V, 100-A, normally-off JFET based solid state circuit breaker (T_{C}=100° C.) subjected to a soft fault condition.

FIG. 8 is a schematic representation of a bidirectional circuit breaker comprising JFETs as saturable unipolar switches and showing an optional bidirectional snubber circuit.

FIG. 9 is a schematic representation of a bidirectional circuit breaker comprising JFETs as saturable unipolar switches and showing a second optional bidirectional snubber circuit.

### DESCRIPTION OF THE VARIOUS EMBODIMENTS

For the purposes of interpreting this specification, the use of “or” herein means “and/or” unless stated otherwise or where the use of “and/or” is clearly inappropriate. The use of “a” herein means “one or more” unless stated otherwise or where the use of “one or more” is clearly inappropriate. The use of “comprise,” “comprises,” “comprising,” “include,” “includes,” and “including” are interchangeable and not intended to be limiting. Furthermore, where the description of one or more embodiments uses the term “comprising,” those skilled in the art would understand that, in some specific instances, the embodiment or embodiments can be alternatively described using the language “consisting essentially of” and/or “consisting of.” It should also be understood that in some embodiments the order of steps or order for performing certain actions is immaterial so long as the present teachings remain operable. Moreover, in some embodiments two or more steps or actions can be conducted simultaneously.

An ideal solid-state circuit breaker should have zero insertion loss. In practice, solid-state circuit breakers should have the lowest practicable insertion loss. In addition, the control circuit should have sufficient bandwidth to detect and disconnect quickly when fault conditions occur. Other desirable features and characteristics of the present invention will become apparent from the subsequent detailed description of the invention and the claims, taken in conjunction with the accompanying drawings and this background of the invention.

As used herein, a wide band gap semiconductor is a semiconductor with an energy band gap greater than 2 eV. Exemplary wide bandgap semiconductor materials include SiC and GaN.

As used herein, a saturable unipolar switching device is a unipolar switching device having a saturation current above which the current passing through the device will cause a voltage drop across the device that is much larger than it would otherwise be without saturation. Suitable saturable unipolar switching devices include JFETs and MOSFETs.

As used herein, a component of a circuit which is “connected to” another component or point in the circuit or “connected between” two components or points in a circuit can be either directly connected or indirectly connected to the other component(s) or point(s) in the circuit.

The design of a solid-state circuit breaker (SSCB) should account for the two types of faults expected: (1) hard shorts and (2) soft faults. Hard shorts, also known as instantaneous faults, can lead to very rapid increases in line current that must be detected and interrupted without delay. Because a source of power protected by a circuit breaker has low internal resistance to the flow of current to be efficient, they also allow large currents to flow during instantaneous faults. Such faults are thus easily distinguished from normal transients leading to a low false trip rate because of the large magnitude of current they create, but they are problematic due to the demand for high bandwidth detection and speedy current interruption. In fact, this problem is why a bipolar device is unsuitable for use in a solid-state circuit breaker. Soft faults, on the other hand, are similar to normal load transients, such as motor starting, but their detection is essential as they can be dangerous if left undetected due to the long period of thermal loading on the entire system, with fire a real threat to the component responsible for the soft fault.

There are various standards to make the soft fault detection decision. For example, the I²t (pronounced “I squared t”) standard allows the time before a positive fault response is initiated to increase as the difference between the magnitude of the current and a critical threshold value declines. The standard uses an approximately constant value for the integral of the square of the circuit breaker current i(t), known as the “action integral”

$${I}^{2} t = {\int }_{0}^{t} {i}^{2} ( τ ) d τ$$

or less accurately as the “let through energy” [1], where t is the period of time before the action, or I²t, threshold is met, to quantitatively specify the decision threshold figure of merit. The maximum action on trip is an adjustable parameter for many programmable circuit breakers. Other figures of merit can also be used in more sophisticated programmable solid-state circuit breakers. The complexity of the decision making process is balanced by the relatively long periods of time allowed to make the decision, ranging from hundreds of milliseconds to hundreds of seconds in most applications. The Underwriter's Laboratory standard for the common molded mechanical circuit breaker is UL 489 [1]. UL 489 provides a standard mechanical circuit breaker time-current characteristic. The delay curves of the UL 489 standard are driven by application requirements for avoiding false trips due to normal load transients in excess of normal (“nominal”) rated current. The minimum time allowed for an “instantaneous” current trip is also defined by the needs of the application. For mechanical circuit breakers, “instantaneous” time-to-trip is specified in the UL 489 standard as less than 100 ms for currents ten times greater than nominal and are still greater than 1 ms for fault currents above 50 times nominal. These slow instantaneous trip times are adequate for protecting the current carrying wires, but they are too slow for more demanding protection requirements. Moreover, such long trip times are not suitable for protecting electronics-based power conversion components, like DC/DC converters, in which detection and trip should occur in less than 10 μs.

The controller for a solid-state circuit breaker can serve many purposes, ranging from protecting sensitive electronic equipment in a industrial plant to permitting remote reset and automated power management on a vehicle such as an aircraft, depending on the intended sophistication of the solid-state circuit breaker. To implement a standard circuit breaker function similar to the UL 489 standard for time-current characteristic, the controller should have an instantaneous trip capability and a delayed trip capability. In addition, a reset function for a tripped circuit breaker and the functionality to open the breaker on command should be supported. Current limiting during fault conditions is a desirable property of a circuit breaker that is rarely efficiently supported by mechanical circuit breakers. To incorporate this feature, some sort of current sensing element/circuit such as a current transformer or a current viewing resistor may be included to feedback information about the value of the current to the controller circuit for determination of fault or non-fault states. The method of current sensing utilized can: 1) add to insertion losses of the solid-state circuit breaker; 2) can be bandwidth limited; or 3) delay the time between when the current is sensed and the time in which the control circuit receives the feedback information.

In the solid-state circuit breaker disclosed in U.S. Pat. No. 5,388,022, a resistive element is connected in series with the solid-state circuit breaker current path. A voltage is generated across the resistive element that is read, compared, amplified, and fed back to the solid-state circuit breaker control circuit. This method, however, adds additional insertion losses in series with the switch elements, as well as introduces bandwidth and delay times associated with the control circuit. Other methods may include replacing the resistive element with a type of magnetic current detector such as a hall-effect sensor or circuit sensing transistor. These methods, however, would also experience bandwidth limitations and insert some delay in the feedback of the detected signal.

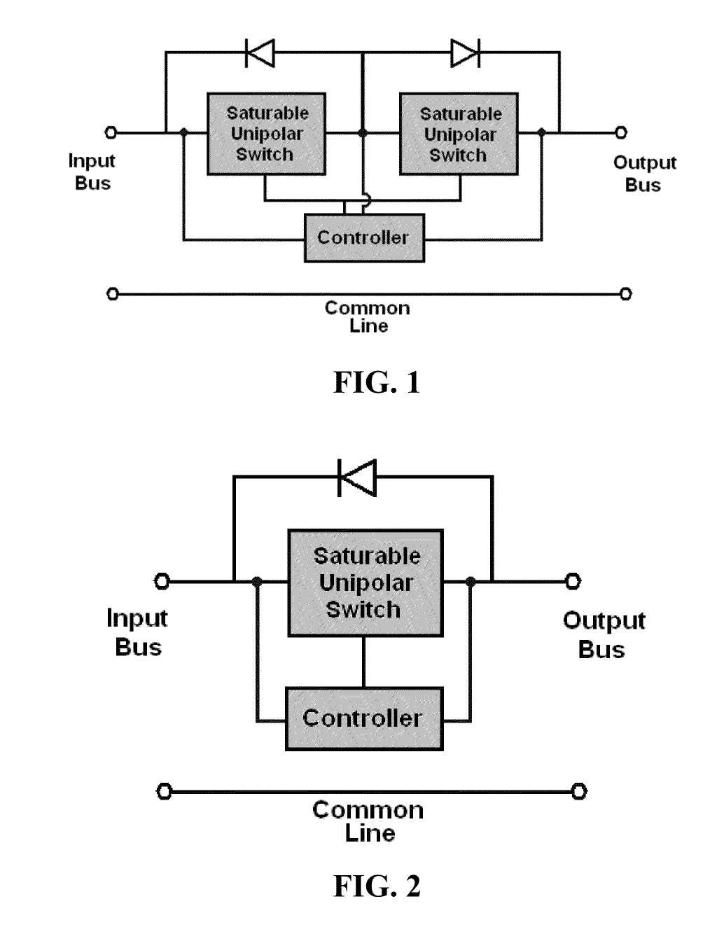

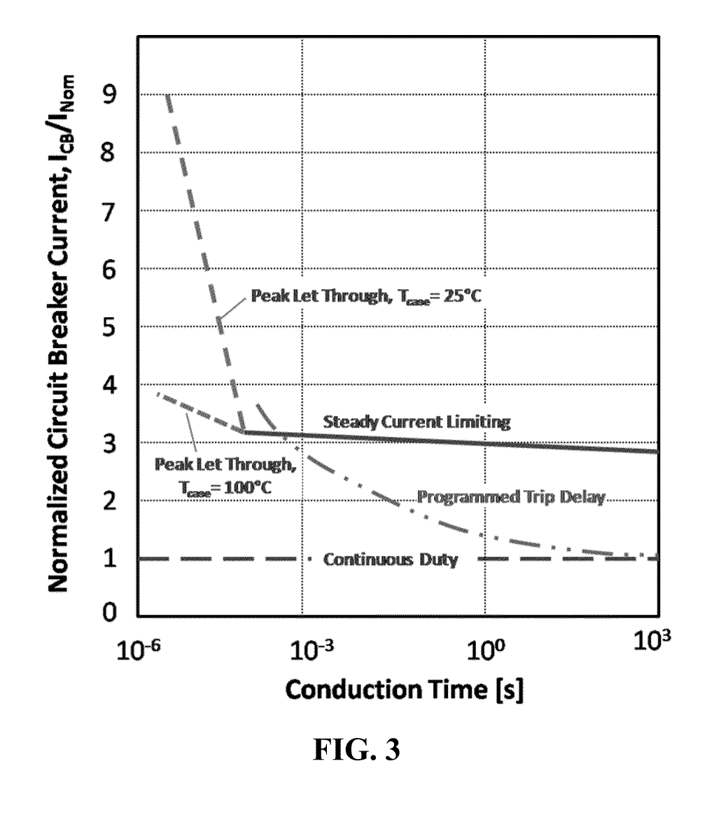

This disclosure teaches a rapid response solid-state circuit breaker (SSCB) capable of instantaneous short circuit current interrupts far faster than that of circuit breakers in use today. The solid-state circuit breaker described herein utilizes the forward conduction characteristics of a saturable unipolar switch in order to develop a voltage sensing method that is proportional to the series current without injecting additional insertion losses or bandwidth limitations. The saturable unipolar switch can be either a junction field effect transistor (JFET) or metal-oxide-semiconductor field effect transistor (MOSFET). The invention can be configured to allow for either bi-directional operation as shown in FIG. 1 or uni-directional operation as shown in FIG. 2.

During conduction, current flows through the series switch or combination of one forward conducting channel and one reverse conducting channel. As shown in FIGS. 1 and 2, the saturable unipolar switch includes an anti-parallel diode. The anti-parallel diode can be a Schottky barrier diode (SBD). SBDs eliminate the need for separate gating and delayed turn-off edges because the diodes always prevent the reverse-blocking FET from developing a V_{DS} less than about −1 V. In the event junction FETs are used as the switching elements in the solid state circuit breaker, this same fact prevents parasitic biasing of the gate-drain diode by clamping V_{DS} such that the gate-to-drain pn-junction forward-bias voltage of approximately 3 V is never reached. This parasitic gate-drain biasing was reported by the Army Research Laboratory during their evaluation of normally-on JFETs for use in solid state circuit breakers configured according to U.S. Pat. No. 3,532,899 [1].

As the drain current through the forward conducting switch increases to between 3 and 9 times above the specified nominal value (depending on junction temperature), the drain-source voltage increases according to the switching I_{D} vs. V_{DS} curve valid for the current junction temperature. The transition to saturation causes V_{DS} to increase rapidly. The fault current is limited by saturation, but the power dissipation in the JFET increases rapidly, too. If the fault is relatively fast, then near adiabatic heating will occur and the JFET saturation current will decrease with the resulting increase in junction temperature. Thus, by using a SiC JFET as a saturable unipolar switch, the circuit breaker is inherently self limiting and can safely withstand short circuit conditions for periods of time orders of magnitude longer than a bipolar device like an IGBT. A SiC JFET is capable of tolerating large surge currents much longer than a comparable silicon device of both the unipolar type (e.g., a MOSFET or JFET) or especially a bipolar type (e.g., an IGBT) due to the high-temperature, thermally rugged features inherent to silicon carbide as a semiconductor material.

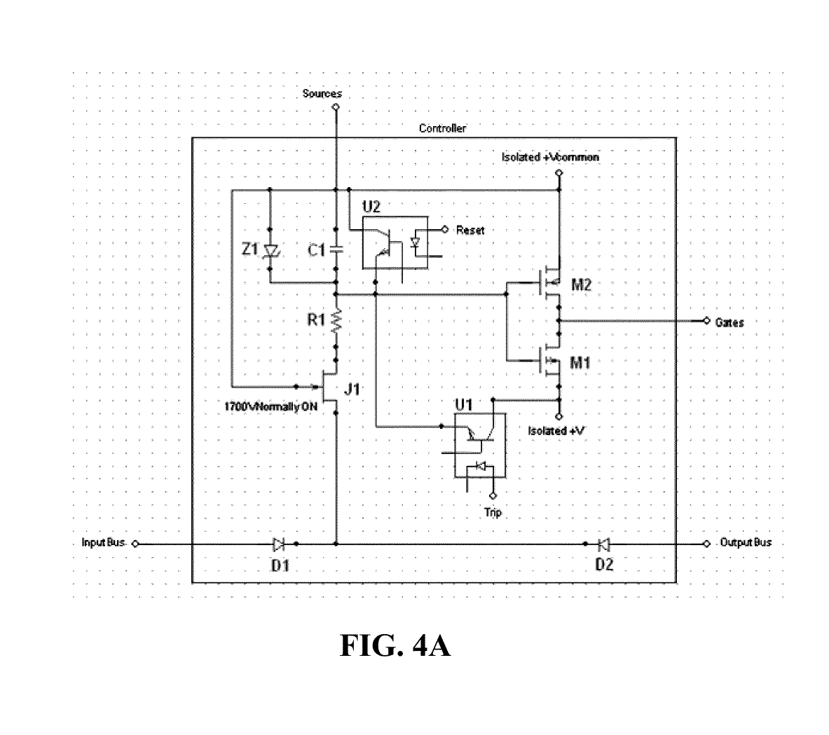

FIG. 3 illustrates the expected current thresholds for instantaneous saturation and for longer dwells after the junction temperature has increased to the typical short circuit condition. The upper curve shows about a 9× multiple above the nominal current. The lower curve shows about a 3× multiple. The former is the maximum or “peak let through” current for hard faults. The latter curve is the expected relaxed let-through current during delayed trip or soft fault conditions in which the junction temperature has increased significantly due to self heating. These multiples are approximately consistent with the standard circuit breaker functional curves provided in UL 489.

The delayed trip can be initiated by a microcontroller according to a pre-programmed function responding to data from a relatively low bandwidth current sensor. One such function among many possible functions is illustrated by the “I²t” curve denoted “programmed trip delay” in FIG. 3 which allows for flexible responses to various current surges that may occur in the normal course of operation so as to avoid undesirable false trips. The microcontroller's command-to-trip can be implemented via the trip-on-command circuitry included in the controller. Suitable microcontroller delay trip schemes are known.

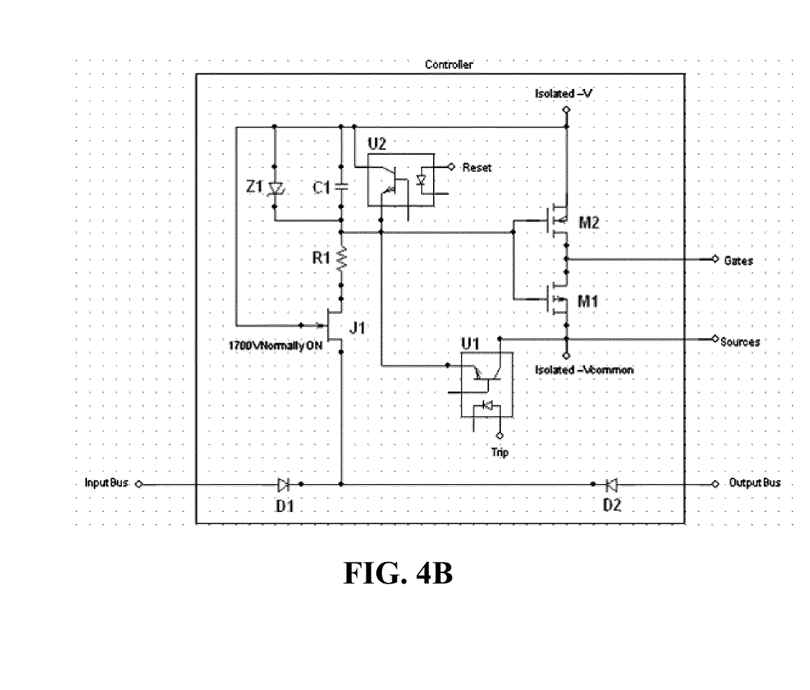

FIG. 4A is a schematic of a rapid response solid-state circuit breaker control circuit which includes reset and trip-on-command circuitry. The controller is adapted for use with normally-off saturable unipolar switches (e.g., normally-off JFETs) by the provision for a small positive bias voltage shown as the “Isolated +V” to sustain conduction in the SiC JFETs when the SSCB is not tripped. In operation, the controller detects hard faults through the onset of saturation. In other words, the forward conducting saturable unipolar switch functions as a current sensor and the onset of current limiting is the signal to trip. Thus, the source and/or the load and the solid-state circuit breaker alike are inherently protected from hard faults by the device's own current limiting. This signal to trip is communicated by the current driven by the rise in the voltage across the forward conducting switch. The current is transmitted through the high-voltage diode between the drain of the solid-state circuit breaker switch that happens to be forward conducting (either on the “Input Bus” side D1 or the “Output Bus” side D2) and the drain of the high-voltage, low-current normally-on SiC JFET labeled J1 in the controller box in FIG. 4A. The voltage rating of the normally-on JFET J1 in the control circuit is selected to exceed the voltage rating of the main solid-state circuit breaker power switches to ensure isolation of the control circuit from the power circuit in the event of over voltage spikes. As the drain voltage of the normally-on JFET J1 rises, the drain current charges the capacitor C1 through the resistor R1 connected to the source of the normally on JFET J1. When the capacitor charges up to the CMOS inverter threshold voltage, the CMOS inverter changes state which shorts the gates of the solid-state circuit breaker switches (i.e., the normally-off saturable unipolar switches). The response of the normally-off saturable unipolar switches is to turn off and break the fault current. For the control circuit shown in FIG. 4A, the polarity of the fault current through the solid-state circuit breaker is immaterial as the symmetry of the controller allows detection in either direction. As used herein, symmetry mean the provision of two diodes, D1 connected to the bus labeled “input” and D2 connected to the bus labeled “output” (although these are interchangeable designations). Either diode can be the conduit of the saturation voltage arising on the drain of the JFET on either side of the breaker, thus triggering a trip event by the controller.

For the case of a uni-directional solid-state circuit breaker, the connection to the output bus, including the second diode D2 connected between the drain of the normally-on JFET and the output bus, would not be included in the control circuit depicted in FIG. 4A.

The overall speed of action of the control circuit depicted in FIG. 4A is governed by the transition of the normally-off JFET into saturation with an optional programmable delay from the RC time constant in the controller. The resistance and capacitance values can be varied to achieve a desired delay. Thus the problem of a high-bandwidth “instantaneous” or rapid trip response circuit breaker is overcome and even sub-microsecond time-to-trip is feasible.

Breaking the conducting path between the source bus and the load causes the drain-source voltage of the forward blocking solid-state circuit breaker switch to rise to the open-circuit bus voltage which maintains the charge in the capacitor C1 with current “leaking” through the normally-on JFET J1 that is in turn self biased into pinch-off by the resistor-capacitor voltage drop. The capacitor voltage is limited by the Zener diode Z1 shown in FIG. 4. The leakage current is limited by the self-biased normally-on JFET J1 which drops the majority of the input bus voltage. This small, low-current JFET J1 is sized to have adequate voltage safety margin.

The high-voltage biasing diode D2 connected to the drain of the non-blocking solid-state circuit breaker switch (i.e., the “Output Bus” terminal in FIG. 4A) prevents bus current from flowing to the load side. Diodes D1 and D2 can be identical and rated with adequate high-voltage margin. In this manner, the solid-state circuit breaker is fully bi-directional and reversible with no preferred input or output terminal. Once tripped, the solid-state circuit breaker will remain tripped as long as the fault at condition is detected. Once the fault condition has cleared, the solid-state circuit breaker will automatically reset based on a predetermined time constant associated with the discharge of the C1 capacitor of the control circuit.

Indefinite lockout on trip can be accomplished with one additional logic element if desired. One of the optocouplers shown in FIG. 4A U2 can be interconnected so that it can reset the CMOS inverter which allows positive gate voltage to be applied to the gates of the normally-off saturable unipolar switches, thus returning the solid-state circuit breaker to the conducting state. The other optocoupler U1 as shown in FIG. 4A can be used to set the CMOS inverter state low so that the gates of the solid-state circuit breaker switches are shorted, thus tripping off the solid state circuit breaker.

The control circuit can also be set up to accommodate the use of normally-on devices as saturable unipolar switches. FIGS. 4B and 4C illustrate control circuits for bi-directional solid state circuit breakers comprising normally-on devices as saturable unipolar switches. In the embodiments depicted in FIGS. 4B and 4C, the source and isolated +Vcommon node of FIG. 4A is a connection to an isolated negative supply voltage (Isolated −V) for turn-off of the normally-on devices. As shown in FIGS. 4B and 4C, the positive or common node for the negative supply voltage is tied to the sources of the saturable unipolar switches.

For devices that require no positive bias, such as some SiC JFETs, the isolated +V node of the controller embodiment depicted in FIG. 4A is connected to the isolated −Vcommon as shown in FIG. 4B. For devices that require a positive bias (e.g., MOSFETs and some SiC JFETS), the totem pole will pull the gates up to a positive supply voltage (Isolated +V) as shown in FIG. 4C. The common connection for both the positive and negative supply voltages of the control circuit depicted in FIG. 4C are tied together and also connected to the source terminals of the saturable unipolar switches.

A controller for normally-on device(s) that do not require a positive bias at turn on is provided. A controller of this type is depicted in FIG. 4B. FIG. 4B is a schematic of a voltage sensing and control circuit for use with normally-on saturable unipolar devices that require no positive bias. Exemplary non-limiting examples of such devices include but are not limited to normally-on SiC JFETs. As shown in FIG. 4B, the controller comprises a CMOS totem pole driver comprising a low voltage N-Channel MOSFET (M2) and a low voltage P-Channel MOSFET (M1). The source terminal of M2 is connected to an isolated negative supply voltage. The drain terminal of M2 is connected to the drain terminal of a P-Channel MOSFET. The gate terminal of M2 is connected to the gate terminal of a P-Channel MOSFET. The source terminal of M1 is connected to the common node of the isolated negative supply voltage. The drain terminal of M1 is connected to the drain terminal of a low voltage N-channel MOSFET. The gate terminal of M1 is connected to the gate terminal of a low voltage N-channel MOSFET. The gates of the two low voltage MOSFETs M1 and M2 are connected to the positive terminal of the capacitor and the cathode of the zener diode and is controlled by the voltage developed across the energy storage capacitor. The energy storage capacitor, the anode of the zener, and the gate of the low-current normally-on JFET of the control circuit are electrically referenced to the isolated negative supply voltage.

A controller for normally-on or normally-off device(s) that require a positive bias at turn on and a negative bias at turn off is also provided. A controller of this type is depicted in FIG. 4C. FIG. 4C is a schematic of a voltage sensing and control circuit for use with normally-on saturable unipolar devices that require some positive bias or normally off saturable unipolar devices that may benefit from some negative bias. Exemplary non-limiting examples of such devices include but are not limited to SiC MOSFETs and normally-on and -off SiC JFETs. As shown in FIG. 4C, the controller according to this embodiment comprises a CMOS totem pole driver comprising a low voltage N-Channel MOSFET (M2) and a low voltage P-Channel MOSFET (M1). The source terminal of M2 is connected to an isolated negative supply voltage. The drain terminal of M2 is connected to the drain terminal of a P-Channel MOSFET. The gate terminal of M2 is connected to the gate terminal of a P-Channel MOSFET. The source terminal of M1 is connected to an isolated positive supply voltage. The drain terminal of M1 is connected to the drain terminal of a low voltage N-channel MOSFET. The gate terminal of M1 is connected to the gate terminal of a low voltage N-channel MOSFET. The gates of the two low voltage MOSFETs M1 and M2 are connected to the positive terminal of the capacitor and cathode of the zener voltage and is controlled by the voltage developed across the energy storage capacitor. The energy storage capacitor, the anode of the zener diode, and the gate of the low-current normally-on JFET of the control circuit are electrically referenced to the isolated negative supply voltage. The common connect of each of the positive and negative voltage supplies are electrically connect together and electrically connected to the source terminals of the SSCB switches.

FIGS. 4B and 4C depict controllers for a bi-directional solid-state circuit breaker comprising two saturable unipolar switches. These controllers can also be adapted for uni-directional solid state circuit breakers. For the case of a uni-directional solid-state circuit breaker, the connection to the output bus, including the second diode D2 connected between the drain of the normally-on JFET and the output bus, would not be included in the control circuits depicted in FIGS. 4B and 4C.

The control circuits shown in FIGS. 4A-4C and described above are merely exemplary and other known control methodologies can be used to turn off the saturable unipolar switch or switches in response to the increase in voltage detected at the saturable unipolar switch or switches upon the onset of saturation.

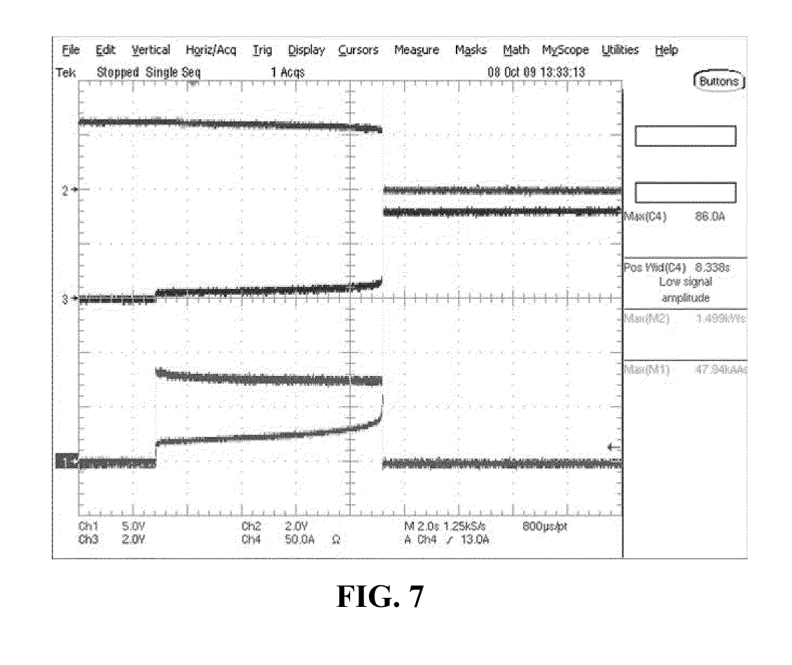

Well known snubber circuits can be included to automatically handle any reaction from parasitic inductance. An exemplary snubber circuit is disclosed in Urciuoli, Army Research Lab, Report No. ARL-MR-0693, May 2008 [1]. This circuit is merely exemplary, however, and other known snubbing techniques and circuits can also be used. A bidirectional circuit breaker comprising a bidirectional snubber circuit 10 according to a first embodiment is shown in FIG. 8. The bidirectional circuit breaker shown in FIG. 8 comprises first and second JFETs 12, 14 as saturable unipolar switches.

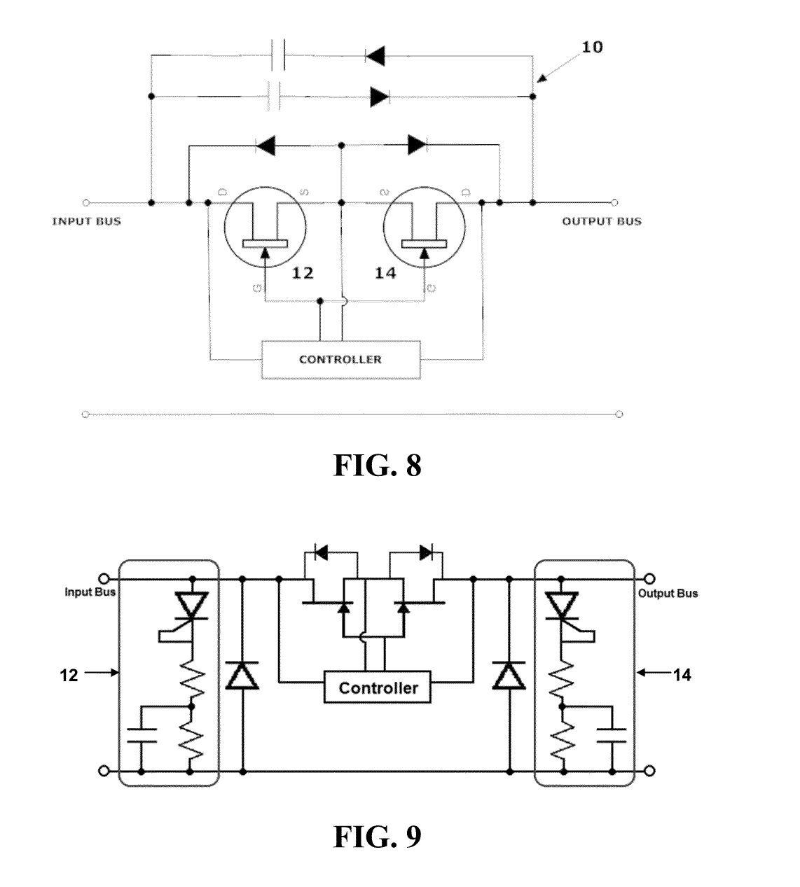

FIG. 9 shows a bidirectional circuit breaker comprising a bidirectional snubber circuit according to a second embodiment. As shown in FIG. 9, the circuit comprises first and second JFETs as saturable unipolar switches input 12 and output 14 snubber circuits. For the device shown in FIG. 9, there is no danger in breaking isolation in the event of a device failure in the snubber as could occur in the circuit of FIG. 8.

A rapid response solid state circuit breaker is described. The circuit breaker includes at least one saturable unipolar switching device such as a power JFET or MOSFET. The JFET can be made of a wide bandgap material The MOSFET can be made of silicon or a wide bandgap material. The circuit breaker can have one voltage bus input and one voltage bus output.

The circuit breaker can be a bidirectional circuit breaker comprising two saturable unipolar switching devices. The drain terminal of the first switching device is connected to the input bus. The drain terminal can also be connected to the anode terminal of diode D1 of the control circuit as shown in FIG. 4A. The source terminal of the first unipolar switching device is connected to the output bus for a uni-directional solid-state circuit breaker configuration or the source terminal of a second unipolar switching device for a bi-directional circuit breaker configuration. If a second unipolar switching device is present, the drain terminal of the second switch is connected to the output bus. The drain terminal of the second switch can also be connected to the anode terminal of diode D2 of the control circuit.

The gate of the first unipolar switching device can be driven by the fault detection control circuit. If a second unipolar switching device is present, both gates are connected together and both gates can be controlled by the same output of the fault detection control circuit. A circuit common is present and is connected to the negative terminal of the input bus and the negative terminal of the output bus.

A voltage sensing control circuit is also provided. The voltage sensing control circuit can comprise:
a manual electronic reset control input (e.g., +5 V);
a manual electronic trip control input (e.g., +5 V);
a power supply input (e.g., +3.3 V or +5 V);
a control circuit common connected to the source terminal(s) of the unipolar switching device(s).
a control circuit output that is connected to the gate terminal(s) of the unipolar switching device(s);
at least one high voltage diode the anode of which is connected to the first input of the control circuit (i.e., the input bus of a uni-directional SSCB) and the cathode of which is connected to the drain of a normally-on JFET;
for the bi-directional solid-state circuit breaker, a second high voltage diode is included whose anode is connected to the second control circuit input (i.e., the output bus) and cathode connected to the cathode of the first high voltage diode and to the drain of a normally-on JFET;
a wide bandgap normally-on JFET (J1) with voltage rating greater than SSCB switch elements;
a small energy storage capacitor (C1);
a charging resistor (R1) that can be used to set the time constant in which the energy storage capacitor charges;
a zener diode (Z1) which can be used to protect the capacitor from charging beyond a specified voltage; and
a CMOS totem pole driver.
   The CMOS totem pole driver comprises a low voltage P-Channel MOSFET (M1) and a low voltage N-Channel MOSFET (M2). The source terminal of the low voltage N-Channel MOSFET (M2) is connected to the control circuit common which is electrically coupled to the source terminal(s) of the saturable unipolar switching element(s). The drain terminal of the P-Channel MOSFET (M1) is connected to the drain terminal of a low voltage N-channel MOSFET. The gate terminal of the P-Channel MOSFET (M1) is connected to the gate terminal of the low voltage N-channel MOSFET. The gates of the two low voltage MOSFETs are connected to the positive terminal of the capacitor and the cathode of the zener diode and is controlled by the voltage developed across the energy storage capacitor.

The controller may also include manual trip and reset points. The manual trip and reset points can comprise optocoupler devices. For example, the controller may include first and second optocoupler devices (U1 and U2), one of which (U1) is used as an electronic manual trip point and the other of which (U2) serves as an electronic manual reset point. The activated optocoupler will hold the gates of the CMOS totem pole either high or low depending on the user selected state.

Programmable I²t functionality can be provided internally by a control signal connection to the gates of the CMOS totem pole driver or externally by control signal connection to the trip and reset inputs.

### Experimental Results

The practice of this invention can be further understood by reference to the following examples, which are provided by way of illustration only are not intended to be limiting.

Instantaneous Trip Testing (i.e. Short Circuit, Hard Fault Condition)

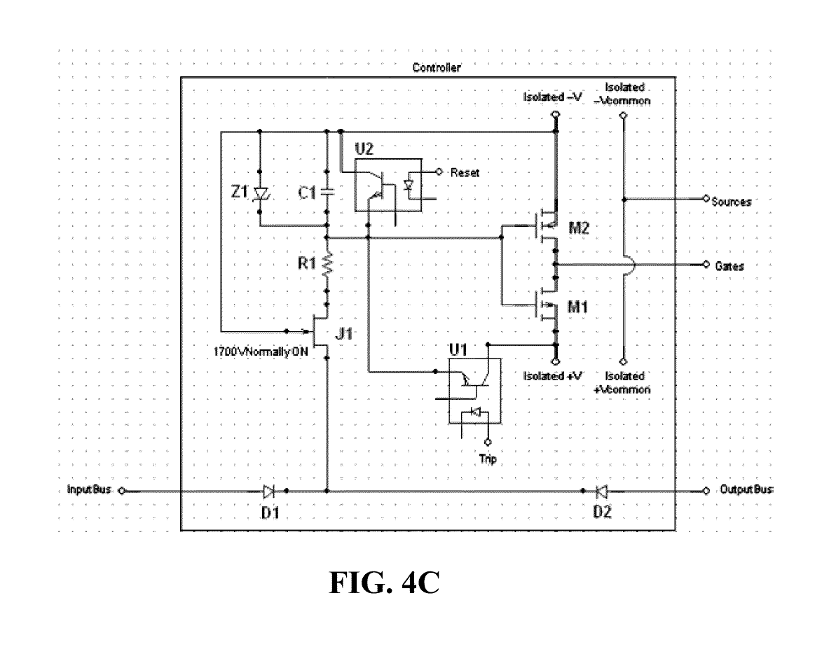

Circuit validation was performed using a bi-directional solid-state circuit breaker comprising two 1200 V, 7 A, normally-off JFETs. Hard fault testing was accomplished using an input bus voltage of 600 V (giving each switch a 2× voltage safety rating). A short circuit event was created at the solid-state circuit breaker output connection to test the control circuit response time. FIG. 5 shows the response of the discrete solid-state circuit breaker to hard fault conditions. Output current was reduced to zero in approximately 4 μs after reaching a peak of 18.6 A. In FIG. 5, the input voltage is 200 V/div, the output voltage is 100 V/div, and the output surge current is 1 V/1 A, 3 V/div (I_{PK}=18.6 A, V_{IN}=600 V, V_{IN}_{_{—}}_{PK}=768 V and T_{C}=25° C.).

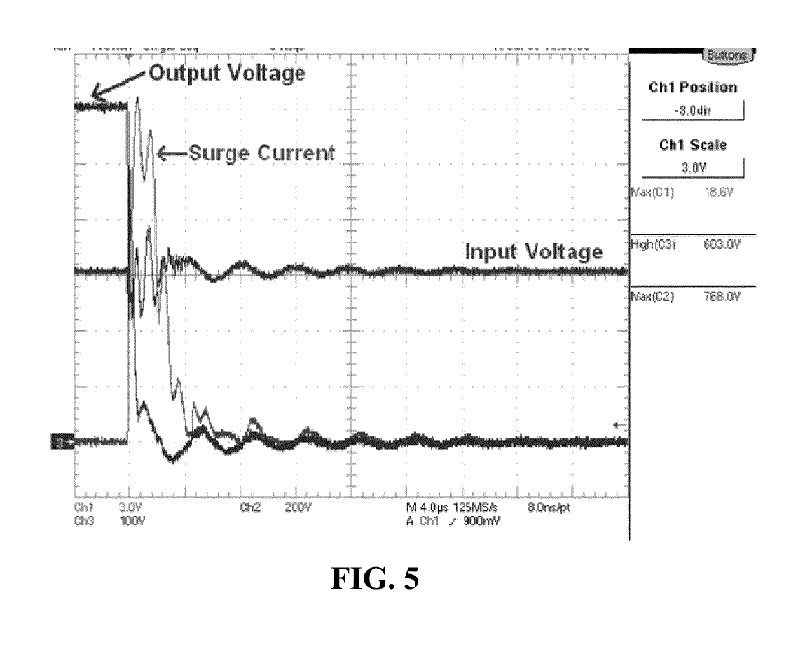

FIG. 6 shows the response of the control circuit in conjunction with a 1200 V, 100 A, normally-off JFET based SSCB to hard fault conditions. Test conditions included an input voltage of 400 V and base plate temperature of 100° C. In FIG. 6, the input voltage is 200 V/div, the output voltage is 200 V/div, and the output surge current is 50 A/div (I_{PK}=206 A, t_{FAULT}=159 μs and T_{C}=100° C.). As can be seen from FIG. 6, the 100 A solid-state circuit breaker was able to quickly disconnect the output from the input with a peak surge current of 206 A that reduced to zero in approximately 159 μs after trip. For each hard fault trip test, the control circuit automatically resets after some preselected time constant (discharge time of the energy store capacitor C1) once the fault condition is cleared. If manual reset is desired prior to the execution of the automatic reset option, a user applied +5 V to the reset pin of the solid-state circuit breaker control circuit will instantly reset the solid-state circuit breaker. Alternatively, a latching logic gate can be used to prevent automatic reset if desired.

Soft Fault Trip Testing (i.e. Over Current)

For this test, the performance of the control circuit response to a soft fault (or over current) condition was analyzed. During this test a preprogrammed I²t control circuit was not employed so that the characteristics of the invented control circuit could be observed. In this test, the normally-off JFETs of the solid-state circuit breaker were allowed to self limit the series current. This self-limiting process causes the drain voltage of the switch to rise to the preselected trip point of the control circuit and command a need for a trip condition. This behavior is identical to the hard fault case. However, the trip duration is extended because the current does not instantly rise to a dangerous value. Instead, during a soft fault the series current is above the nominal circuit breaker rated current but not yet at a dangerous level for the switch elements. As the current continues to flow, the device will begin to heat causing an increase in drain voltage until the designated trip point is reached.

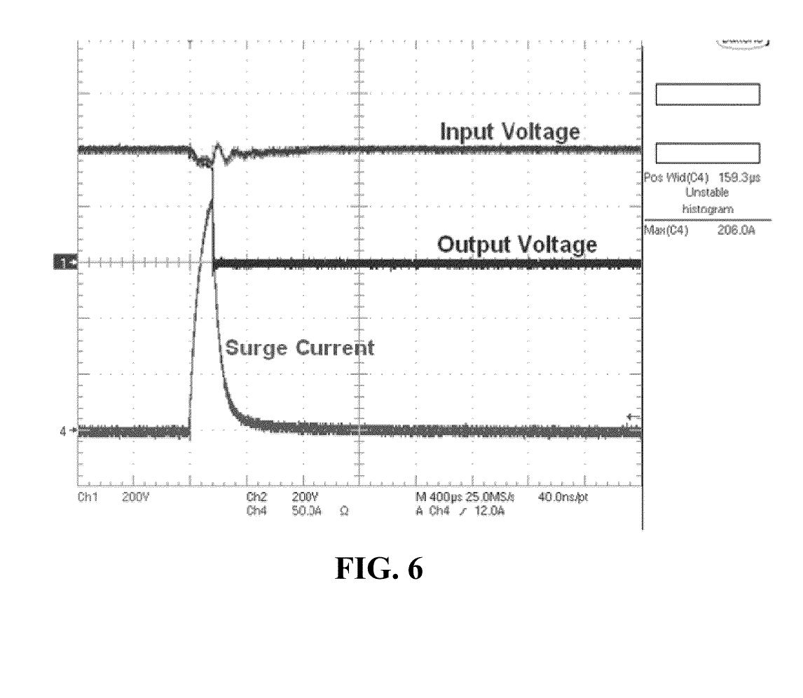

FIG. 7 shows measured waveforms for the 1200 V, 100 A, normally-off JFET based SSCB (T_{C}=100° C.) subjected to a soft fault condition. In FIG. 7, the output current is 50 A/div, V_{DS(ON)} is 5 V/div, totem pole gate voltage is 2 V/div, and the source side voltage of the normally-on JFET of the sensing circuit is 2 V/div (I_{OUT}_{_{—}}_{PK}=86 A, I_{LIM}=75 A and T_{FAULT}=8.34 s). The output current is self-limited by the JFETs at 75 A for more than 8 s before the trip circuit initiates a fault detection. The JFET limited fault current does not follow a typical I²t curve and thus an additional circuit would be required to calculate an I²t curve for the controller to follow if this type of soft fault trip condition is required for a specific application. This experiment demonstrates the superior short-circuit properties of the SiC JFET and a useful property that gives both safety and flexibility to the resulting solid state circuit breaker because fault currents are self-limited until a programmable trip delay response can be imposed.

While the foregoing specification teaches the principles of the present invention, with examples provided for the purpose of illustration, it will be appreciated by one skilled in the art from reading this disclosure that various changes in form and detail can be made without departing from the true scope of the invention.

### REFERENCES

[1] D. P. Urciuoli, “Evaluation of SiC VJFET Devices for Scalable Solid-State Circuit Breakers,” Army Research Lab, Report# ARL-MR-0693, May 2008.
[2] U.S. Pat. No. 3,532,899 to Huth, et. al. entitled “Field-Effect Electronic Switch,” issued on Oct. 6, 1970.
[3] U.S. Pat. No. 5,388,022 to Ahuja entitled “Auto Reset Circuit Breaker,” issued on Feb. 7, 1995.

What is claimed is:

1. A circuit breaker comprising:
a first saturable unipolar switch comprising a source a gate and a drain;
a first diode connected between the source and the drain of the first saturable unipolar switch, wherein the cathode of the first diode is connected to the drain of the first saturable unipolar switch;
a controller adapted to detect current generated upon the onset of saturation in the first saturable unipolar switch, wherein the controller is adapted to supply a first voltage to the gate of the first saturable unipolar switch when saturation of the first saturable unipolar switch is not detected, wherein the controller is adapted to supply a second voltage to the gate of the first saturable unipolar switch when saturation of the first saturable unipolar switch is detected, and wherein the first saturable unipolar switch is in an on state when the first voltage is applied to the gate and in an off state when the second voltage is applied to the gate.

2. The circuit breaker of claim 1, further comprising:
a second saturable unipolar switch comprising a source a gate and a drain, wherein the source of the second saturable unipolar switch is connected to the source of the first saturable unipolar switch; and
a second diode connected between the source and the drain of the second saturable unipolar switch, wherein the cathode of the second diode is connected to the drain of the second saturable unipolar switch; and
wherein the controller is adapted to detect current generated upon the onset of saturation in the second saturable unipolar switch, wherein the controller is adapted to supply the first voltage to the gate of the second saturable unipolar switch when saturation of the second saturable unipolar switch is not detected and wherein the controller is adapted to supply the second voltage to the gate of the second saturable unipolar switch when saturation of the second saturable unipolar switch is detected, and wherein the second saturable unipolar switch is in an on state when the first voltage is applied to the gate and in an off state when the second voltage is applied to the gate.

3. The circuit breaker of claim 1, wherein the first saturable unipolar switch is a normally-off device.

4. The circuit breaker of claim 1, wherein the first saturable unipolar switch is a normally-on device.

5. The circuit breaker of claim 1, wherein the first saturable unipolar switch is a normally-off SiC JFET.

6. The circuit breaker of claim 1, wherein the diode connected between the source and the drain of the first saturable unipolar switch is a Schottky barrier diode.

7. The circuit breaker of claim 1, wherein the first saturable unipolar switch is a metal-oxide semiconductor field effect transistor (MOSFET) or a wide bandgap junction field effect transistor (JFET).

8. The circuit breaker of claim 3, wherein the controller comprises:
a power supply input;
a first control input connected to the drain of the first saturable unipolar switch;
a control output connected to the gate of the first saturable unipolar switch;
a control common connected to the source of the first saturable unipolar switch;
a diode (D1) connected to the first control input, wherein the anode of the diode (D1) is connected to the first control input;
a normally-on JFET (J1), wherein the drain of the normally-on JFET (J1) is connected to the cathode of the diode (D1);
a resistor (R1) connected to the source of the normally-on JFET (J1)
a capacitor (C1) connected in series with the resistor (R1), wherein the positive terminal of the capacitor is connected to the resistor (R1) and the negative terminal of the capacitor is connected to the control common;
a Zener diode (Z1) in parallel with the capacitor (C1) such that the cathode of the zener diode (Z1) is connected to the positive terminal of the capacitor (C1);
a CMOS totem pole driver comprising:
an N-Channel MOSFET (M2) comprising a source a gate and a drain, wherein the source terminal is connected to the control common;
a P-Channel MOSFET (M1) comprising a source a gate and a drain, wherein the source is connected to the power supply input, the drain is connected to the drain terminal of a low voltage N-channel MOSFET (M2) to form a common drain and the gate terminal is connected to the gate terminal of the low voltage N-channel MOSFET (M2) to form a common gate;
wherein the common gate of the CMOS totem pole driver is connected to the positive terminal of the capacitor (C1) and wherein the common drain of the CMOS totem pole driver is connected to the control output.

9. The circuit breaker of claim 8, further comprising an isolated positive power supply comprising a positive terminal and a common terminal, wherein the positive terminal is connected to the power supply input and wherein the common terminal is connected to the control common.

10. The circuit breaker of claim 4, wherein the controller comprises:
a power supply input;
a first control input connected to the drain of the first saturable unipolar switch;
a control output connected to the gate of the first saturable unipolar switch;
a control common connected to the source of the first saturable unipolar switch;
a diode (D1) connected to the first control input, wherein the anode of the diode (D1) is connected to the first control input;
a normally-on JFET (J1), wherein the drain of the normally-on JFET (J1) is connected to the cathode of the diode (D1);
a resistor (R1) connected to the source of the normally-on JFET (J1)
a capacitor (C1) connected in series with the resistor (R1), wherein the positive terminal of the capacitor is connected to the resistor (R1) and the negative terminal of the capacitor is connected to the power supply input;
a Zener diode (Z1) in parallel with the capacitor (C1) such that the cathode of the zener diode (Z1) is connected to the positive terminal of the capacitor (C1);
a CMOS totem pole driver comprising:
an N-Channel MOSFET (M2) comprising a source a gate and a drain, wherein the source terminal is connected to the power supply input;
a P-Channel MOSFET (M1) comprising a source a gate and a drain, wherein the source is connected to the control common, the drain is connected to the drain terminal of a low voltage N-channel MOSFET (M2) to form a common drain and the gate terminal is connected to the gate terminal of the low voltage N-channel MOSFET (M2) to form a common gate;
wherein the common gate of the CMOS totem pole driver is connected to the positive terminal of the capacitor (C1) and wherein the common drain of the CMOS totem pole driver is connected to the control output.

11. The circuit breaker of claim 10, further comprising an isolated negative power supply comprising a negative terminal and a common terminal, wherein the negative terminal is connected to the power supply input and wherein the common terminal is connected to the control common.

12. The circuit breaker of claim 4, wherein the controller comprises:
a first power supply input;
a second power supply input;
a first control input connected to the drain of the first saturable unipolar switch;
a control output connected to the gate of the first saturable unipolar switch;
a control common connected to the source of the first saturable unipolar switch;
a diode (D1) connected to the first control input, wherein the anode of the diode (D1) is connected to the first control input;
a normally-on JFET (J1), wherein the drain of the normally-on JFET (J1) is connected to the cathode of the diode (D1);
a resistor (R1) connected to the source of the normally-on JFET (J1)
a capacitor (C1) connected in series with the resistor (R1), wherein the positive terminal of the capacitor is connected to the resistor (R1) and the negative terminal of the capacitor is connected to the first power supply input;
a Zener diode (Z1) in parallel with the capacitor (C1) such that the cathode of the zener diode (Z1) is connected to the positive terminal of the capacitor (C1);
a CMOS totem pole driver comprising:
an N-Channel MOSFET (M2) comprising a source a gate and a drain, wherein the source terminal is connected to the first power supply input;
a P-Channel MOSFET (M1) comprising a source a gate and a drain, wherein the source is connected to the second power supply input, the drain is connected to the drain terminal of a low voltage N-channel MOSFET (M2) to form a common drain and the gate terminal is connected to the gate terminal of the low voltage N-channel MOSFET (M2) to form a common gate;
wherein the common gate of the CMOS totem pole driver is connected to the positive terminal of the capacitor (C1) and wherein the common drain of the CMOS totem pole driver is connected to the control output.

13. The circuit breaker of claim 12, further comprising:
an isolated negative power supply comprising a negative terminal and a common terminal, wherein the negative terminal of the isolated negative power supply is connected to the first power supply input and wherein the common terminal of the isolated negative power supply is connected to the control common; and
an isolated positive power supply comprising a positive terminal and a common terminal, wherein the positive terminal of the isolated positive power supply is connected to the second power supply input and wherein the common terminal of the isolated positive power supply is connected to the control common.

14. The circuit breaker of claim 2, wherein the first and second saturable unipolar switches are normally-off devices and wherein the controller comprises:
a power supply input;
a first control input connected to the drain of the first saturable unipolar switch;
a second control input connected to the drain of the second saturable unipolar switch;
a control output connected to the gate of the first saturable unipolar switch and the gate of the second saturable unipolar switch;
a control common connected to the source of the first saturable unipolar switch and the source of the second saturable unipolar switch;
a diode (D1) connected to the first control input, wherein the anode of the diode (D1) is connected to the first control input;
a diode (D2) connected to the second control input, wherein the anode of the diode (D2) is connected to the second control input;
a normally-on JFET (J1), wherein the drain of the normally-on JFET (J1) is connected to the cathode of the diode (D1) and the cathode of the diode (D2);
a resistor (R1) connected to the source of the normally-on JFET (J1)
a capacitor (C1) connected in series with the resistor (R1), wherein the positive terminal of the capacitor is connected to the resistor (R1) and the negative terminal of the capacitor is connected to the control common;
a Zener diode (Z1) in parallel with the capacitor (C1) such that the cathode of the zener diode (Z1) is connected to the positive terminal of the capacitor (C1);
a CMOS totem pole driver comprising:
an N-Channel MOSFET (M2) comprising a source a gate and a drain, wherein the source terminal is connected to the control common;
a P-Channel MOSFET (M1) comprising a source a gate and a drain, wherein the source is connected to the power supply input, the drain is connected to the drain terminal of a low voltage N-channel MOSFET (M2) to form a common drain and the gate terminal is connected to the gate terminal of the low voltage N-channel MOSFET (M2) to form a common gate;
wherein the common gate of the CMOS totem pole driver is connected to the positive terminal of the capacitor (C1) and wherein the common drain of the CMOS totem pole driver is connected to the control output.

15. The circuit breaker of claim 14, further comprising an isolated positive power supply comprising a positive terminal and a common terminal, wherein the positive terminal is connected to the power supply input and wherein the common terminal is connected to the control common.

16. The circuit breaker of claim 2, wherein the first and second saturable unipolar switches are normally-on devices and wherein the controller comprises:
a power supply input;
a first control input connected to the drain of the first saturable unipolar switch;
a second control input connected to the drain of the second saturable unipolar switch;
a control output connected to the gate of the first saturable unipolar switch and the gate of the second saturable unipolar switch;
a control common connected to the source of the first saturable unipolar switch and the source of the second saturable unipolar switch;
a diode (D1) connected to the first control input, wherein the anode of the diode (D1) is connected to the first control input;
a diode (D2) connected to the second control input, wherein the anode of the diode (D2) is connected to the second control input;
a normally-on JFET (J1), wherein the drain of the normally-on JFET (J1) is connected to the cathode of the diode (D1) and the cathode of the diode (D2);
a resistor (R1) connected to the source of the normally-on JFET (J1)
a capacitor (C1) connected in series with the resistor (R1), wherein the positive terminal of the capacitor is connected to the resistor (R1) and the negative terminal of the capacitor is connected to the power supply input;
a Zener diode (Z1) in parallel with the capacitor (C1) such that the cathode of the zener diode (Z1) is connected to the positive terminal of the capacitor (C1);
a CMOS totem pole driver comprising:
an N-Channel MOSFET (M2) comprising a source a gate and a drain, wherein the source terminal is connected to the power supply input;
a P-Channel MOSFET (M1) comprising a source a gate and a drain, wherein the source is connected to the control common, the drain is connected to the drain terminal of a low voltage N-channel MOSFET (M2) to form a common drain and the gate terminal is connected to the gate terminal of the low voltage N-channel MOSFET (M2) to form a common gate;
wherein the common gate of the CMOS totem pole driver is connected to the positive terminal of the capacitor (C1) and wherein the common drain of the CMOS totem pole driver is connected to the control output.

17. The circuit breaker of claim 16, further comprising an isolated negative power supply comprising a negative terminal and a common terminal, wherein the negative terminal is connected to the power supply input and wherein the common terminal is connected to the control common.

18. The circuit breaker of claim 2, wherein the first and second saturable unipolar switches are normally-on devices and wherein the controller comprises:
a first power supply input;
a second power supply input;
a first control input connected to the drain of the first saturable unipolar switch;
a second control input connected to the drain of the second saturable unipolar switch;
a control output connected to the gate of the first saturable unipolar switch and the gate of the second saturable unipolar switch;
a control common connected to the source of the first saturable unipolar switch and the source of the second saturable unipolar switch;
a diode (D1) connected to the first control input, wherein the anode of the diode (D1) is connected to the first control input;
a diode (D2) connected to the second control input, wherein the anode of the diode (D2) is connected to the second control input;
a normally-on JFET (J1), wherein the drain of the normally-on JFET (J1) is connected to the cathode of the diode (D1) and the cathode of the diode (D2);
a resistor (R1) connected to the source of the normally-on JFET (J1)
a capacitor (C1) connected in series with the resistor (R1), wherein the positive terminal of the capacitor is connected to the resistor (R1) and the negative terminal of the capacitor is connected to the first power supply input;
a Zener diode (Z1) in parallel with the capacitor (C1) such that the cathode of the zener diode (Z1) is connected to the positive terminal of the capacitor (C1);
a CMOS totem pole driver comprising:
an N-Channel MOSFET (M2) comprising a source a gate and a drain, wherein the source terminal is connected to the first power supply input;
a P-Channel MOSFET (M1) comprising a source a gate and a drain, wherein the source is connected to the second power supply input, the drain is connected to the drain terminal of a low voltage N-channel MOSFET (M2) to form a common drain and the gate terminal is connected to the gate terminal of the low voltage N-channel MOSFET (M2) to form a common gate;
wherein the common gate of the CMOS totem pole driver is connected to the positive terminal of the capacitor (C1) and wherein the common drain of the CMOS totem pole driver is connected to the control output.

19. The circuit breaker of claim 18, further comprising:
an isolated negative power supply comprising a negative terminal and a common terminal, wherein the negative terminal of the isolated negative power supply is connected to the first power supply input and wherein the common terminal of the isolated negative power supply is connected to the control common; and
an isolated positive power supply comprising a positive terminal and a common terminal, wherein the positive terminal of the isolated positive power supply is connected to the second power supply input and wherein the common terminal of the isolated positive power supply is connected to the control common.

20. The circuit breaker of claim 8, wherein the power supply input is connected to a 3.3 V or a 5 V power supply.

21. The circuit breaker of claim 8, further comprising:
a reset control which, when activated, connects the common gate of the CMOS totem pole driver to the control common; and/or
a trip control which, when activated, connects the common gate of the CMOS totem pole driver to the power supply input.

22. The circuit breaker of claim 21, wherein the reset control and/or the trip control comprise an optocoupler.

23. The circuit breaker of claim 8, further comprising a controller adapted to provide a control signal to the common gate of the CMOS totem pole driver.

24. The circuit breaker of claim 21, further comprising a controller adapted to provide a control signal to the reset control and/or the trip control.

25. The circuit breaker of claim 8, wherein the voltage rating of the normally-on JFET (J1) is greater than the voltage rating of the first saturable unipolar switch.

26. The circuit breaker of claim 1, further comprising a snubber circuit.

27. A circuit comprising the circuit breaker of claim 1.

28. The circuit of claim 27, further comprising a current sensor in series with the circuit breaker, wherein the current sensor is connected to the controller and wherein the controller is adapted to apply the second voltage to the gate of the first saturable unipolar switch when the current sensor detects a current in the circuit above a predetermined value.

29. The circuit of claim 28, wherein the predetermined value of current is a function of the square of the current (I²) and the time (t) the current is passing through the circuit.
